(19) United States
(12) Patent Application Publication
(10) Pub. No.: US 2026/0237430 A1
(43) Pub. Date: Aug. 13, 2026

(54) MEMORY DEVICES WITH SELECTIVE TRACKING SCHEME AND METHODS FOR OPERATING THE SAME

(71) Applicant: Taiwan Semiconductor Manufacturing Company, Ltd., Hsinchu (TW)

(72) Inventors: Wei-Yu Lin, Hsinchu City (TW); Li-Yue Huang, Hsinchu City (TW); Ming-Hung Chang, Hsinchu City (TW); Ching-Wei Wu, Hsinchu City (TW)

(21) Appl. No.: 19/244,124

(22) Filed: Jun. 20, 2025

Related U.S. Application Data
(60) Provisional application No. 63/757,984, filed on Feb. 13, 2025.
(60) Provisional application No. 63/769,315, filed on Mar. 10, 2025.

(51) Int. Cl. G11C 11/418; G11C 5/14; G11C 11/419

(52) U.S. Cl. CPC G11C 11/418; G11C 5/147; G11C 11/419

(57) ABSTRACT

A circuit includes a memory array comprising nominal memory cells and at least a tracking memory cell, the tracking memory cell coupled to a tracking bit line and a tracking word line; a comparator configured to compare a reference voltage with a varying supply voltage to determine a logic state of a mode selection signal; and a controller. The controller can, in response to a first logic state of the mode selection signal, provide a first signal on the tracking word line and provide a second signal to reset the first signal based on a third signal present along a first discharging path; and, in response to a second logic state of the mode selection signal, provide the first signal on the tracking word line and provide the second signal based on a fourth signal configured to form a second discharging path.

### CROSS-REFERENCE TO RELATED APPLICATION

This application claims priority to and the benefit of U.S. Provisional Application No. 63/757,984, filed Feb. 13, 2025, and U.S. Provisional Application No. 63/769,315, filed Mar. 10, 2025, each of which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device including a memory controller, in accordance with some embodiments.

FIG. 2 illustrates an example schematic diagram of the memory controller of FIG. 1, in accordance with some embodiments.

FIG. 3 illustrates example waveforms of various signals when operating the memory device in different operation modes, in accordance with some embodiments.

FIG. 4 illustrates another example schematic diagram of the memory controller of FIG. 1, in accordance with some embodiments.

FIG. 5 illustrates yet another example schematic diagram of the memory controller of FIG. 1, in accordance with some embodiments.

FIG. 6 illustrates an example flow chart for operating the memory device of FIG. 1, in accordance with some embodiments.

FIG. 7 illustrates an example plot of one or more performance characteristics versus a varying supply voltage of the memory device of FIG. 1, in accordance with some embodiments.

FIGS. 8, 9, and 10 illustrate example circuit diagrams of a tracking memory cell of the memory device of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A static random access memory (SRAM) device is a type of volatile semiconductor memory that stores data bits using bistable circuitry that does not need refreshing. An SRAM cell may be referred to as a bit cell because it stores one bit of information, represented by the logic state of two cross coupled inverters. Memory arrays include multiple bit cells arranged in rows and columns. Each bit cell in a memory array typically includes connections to a power supply voltage and to a reference voltage. Logic signals on bit lines control reading from and writing to a bit cell, with a word line controlling connections of the bit lines to the inverters. A word line may be coupled to the bit cells in a row of a memory array, with different word lines provided for different rows.

Each successive bit cell along a bit line or word line has a characteristic input capacitance, and each conductor leg (e.g., a part of bit line or word line) between bit cells has a resistance, leading to a signal propagation delay. The delay is longer for bit cells that are farther than others along signal paths beginning at the source of memory addressing and control signals, such as the outputs of address decoding gates and line drivers coupled at an edge of the memory array. The delay affects the time needed to access the bit cells and limits the highest frequency at which the memory can be operated. The time taken to access an SRAM bit cell, e.g., for a read/write operation, may vary due to several factors including the relative position of the accessed bit cell within the SRAM array. Reliable estimation of SRAM timing characteristics is important for ensuring consistency in system components and high system performance.

In this regard, various techniques have been proposed to provide timing tracking functionality for accurate, efficient monitoring of an SRAM device. Timing tracking enables determination of when a nominal memory cell finishes a read or write operation. For example, tracking cells, which are substantially similar to the nominal memory cells that store data, are enlisted or repurposed to provide a signal for controlling the timing of memory operations. In general, a tracking cell is connected to a tracking word line and a tracking bit line. The timing with which the tracking cell pulls down a voltage on the tracking bit line triggers (e.g., transitions) a reset signal to reset (e.g., pull down) a pulse present on the tracking word line to terminate the timing tracking.

To accommodate various applications, it has been proposed to operate the SRAM device with a varying supply voltage. For example, when configured in a high-performance mode, the supply voltage may be provided with a higher voltage level; and configured in a normal-performance mode, the supply voltage may be provided with a lower voltage level. However, a delay induced from the tracking memory cells becomes the bottleneck of a maximum operating frequency (sometimes referred to as “Fmax”) of the SRAM device when operating with the high supply voltage. Further, due to the universal tracking scheme being applied regardless of whether the SRAM device operates with the high or low supply voltage, a read margin and a write margin of the SRAM device are generally wasted when operating with the high supply voltage. Disadvantageously, the existing SRAM device may thus consume additional power. Thus, the existing timing tracking techniques or corresponding circuits for an SRAM device have not been entirely optimized in certain aspects.

The present disclosure provides various embodiments of a memory device including a controller, a comparator, and at least one memory array with a plurality of nominal memory cells and one or more tracking memory cells. The nominal memory cells are each configured to store a data bit, and the tracking memory cells are configured to provide signals for determination on timing tracking. For example, the controller can receive a mode selection signal from the comparator configured to compare a supply voltage having a varying voltage level (e.g., first and second voltage levels) with a reference voltage. The mode selection signal may be provided with a first logic state (sometimes referred to as the memory device being configured in a non-turbo mode), when the varying supply voltage is equal to or less than the reference voltage; and the mode selection signal may be provided with a second logic state (sometimes referred to as the memory device being configured in a turbo mode), when the varying supply voltage is higher than the reference voltage.

In the non-turbo mode (sometime referred to as a normal-performance mode), the controller can provide a tracking word line signal to activate the tracking memory cells, and provide a first reset signal to reset the tracking word line signal based on a tracking bit line signal; and in the turbo mode (sometime referred to as a high-performance mode), the controller can provide a second (or intermediate) reset signal directly based on the tracking word line signal, and directly transition the first reset signal with the second reset signal. In other words, during the non-turbo mode, the tracking word line signal may transition (e.g., to logic 0), based on the timing that the first rest signal transitions (e.g., to logic 1) according to the tracking bit line signal; and during the turbo mode, the tracking word line signal does not have to wait until the timing tracking is finished and can transition upon the second reset signal transitioning (e.g., to logic 1).

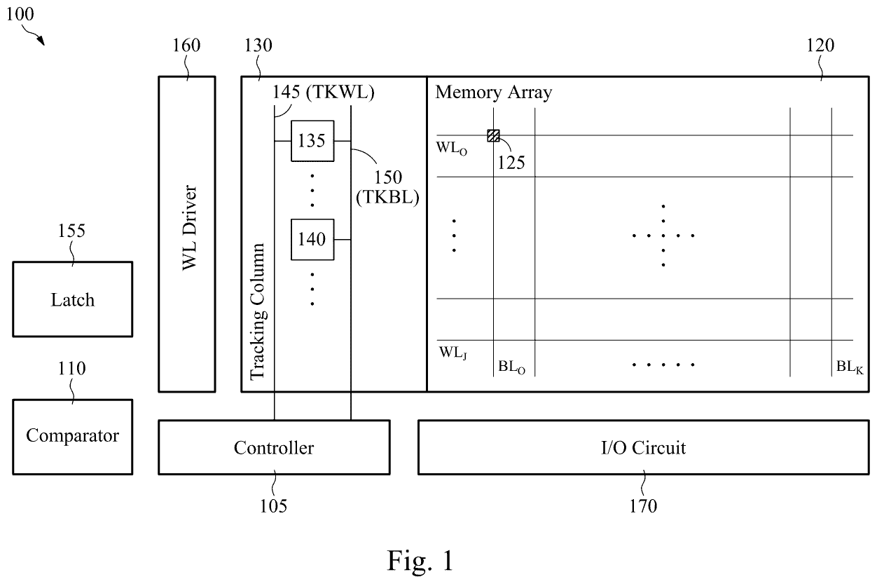

FIG. 1 illustrates an example block diagram of a memory device 100, in accordance with various embodiments. The memory device 100 shown in FIG. 1 has been simplified for illustration purposes, and thus, it should be appreciated that the memory device 100 can include any of various other components while remaining within the scope of the present disclosure.

As shown, the memory device 100 includes a memory controller 105, a comparator 110, and a memory array 120. The memory array 120 may include a plurality of storage circuits or memory cells 125 arranged in two-or three-dimensional arrays. Each memory cell 125 may be coupled to a corresponding word line (WL) and one or more corresponding bit lines (BLs). The memory controller 105 can write data to or read data from the memory array 120 according to electrical signals through the word lines WLs and bit lines BLs. Further, according to various embodiments of the present disclosure, the memory controller 105 can adjust a tracking scheme based on a mode selection signal provided by the comparator 110, which will be discussed in further detail below. In other embodiments, the memory device 100 includes more, fewer, or different components than shown in FIG. 1.

The memory array 120 is a hardware component that stores data. In some embodiments, the memory array 120 includes a plurality of storage circuits or memory cells 125. The memory array 120 includes word lines WL₀ . . . WL_{J}, each extending in a first direction (e.g., the X-direction) and bit lines BL₀ . . . BL_{K}, each extending in a second direction (e.g., the Y-direction). In some embodiments, the memory array 120 may be referred to as having a number of columns and a number of rows, where each of the columns corresponds to a respective one of the bit lines BLs and each of the rows corresponds to a respective one of the word lines WLs. Stated another way, the memory array 120 can include K columns and J rows of the memory cells 125. The word lines WLs and the bit lines BLs may be conductive metals or conductive rails. Each memory cell 125 is coupled to a corresponding word line WL and a corresponding pair of bit lines BL (BL and BLB), and can be operated according to voltages or currents through the corresponding word line, WL, and the corresponding bit lines, BL and BLB.

In some embodiments, each memory cell 125 may include a volatile memory, a non-volatile memory, or a combination of them. Each memory cell 125 is embodied as a static random access memory (SRAM) cell or other type of memory cell. For example, the memory cell 125 may be is implemented as a six-transistor (6T) static random access memory (SRAM) cell that consists of six transistors. Generally, the nominal memory cell 125 includes a pair of access or pass-gate transistors, PG1 and PG2, biased by (e.g., gated by) the corresponding word line WL. The pass-gate transistors PG1 and PG2 provide access to cross-coupled first and second inverters, respectively. The pass-gate transistors PG1 and PG2 can pass bit lines signals to internal nodes of the cross-coupled inverters, when the WL signal fed into the gate terminals of the pass-gate transistors PG1 and PG2 becomes true. The first inverter includes a pull-up (e.g., PMOS) transistor PU1 and a pull-down (e.g., NMOS) transistor PD1, and the second inverter includes a pull-up (e.g., PMOS) transistor PU2 and a pull-down (e.g., NMOS) transistor PD2. The pass-gate transistors PG1 and PG2 are respectively coupled to corresponding pair of bit lines (first and second bit lines), BL and BLB. This configuration is generally referred to as a 6T (six-transistor) configuration.

During a standby mode, the word line WL is not asserted, and thus the pass-gate transistors PG1 and PG2 disconnect the memory cell 125 from the bit lines, BL and BLB. The cross-coupled inverters are coupled between power supplies (VDD and VSS), and reinforce each other to maintain one of two possible logic states with a stored data bit at one of the internal nodes between the inverters (sometimes referred to as a node Q or node BL_IN) and the complement of that bit at the other node between the inverters (sometimes referred to as a node QB or node BLB_IN). During a read operation, the bit lines, BL and BLB, are pre-charged to a high logic state (e.g., logic 1), and the word line WL is asserted. The stored data bit at the node Q is transferred to the first bit line BL, and the data bit at the node QB is transferred to the second bit line BLB. During a write operation, the value to be written is provided at the first bit line BL, and the complement of that value is provided at the second bit line BLB, when the word line WL is asserted. Although the 6T SRAM cells are herein described as an example implementation of the memory cell 125, it should be understood that the memory cell 125 can be implemented as other types of memory cells, including types of memory other than SRAM and other types of SRAM configurations than 6T (e.g., eight transistor (8T) or ten transistor (10T) configurations) while remaining within the scope of the present disclosure.

In addition to the memory cells 125 configured to store data (which are sometimes referred to as nominal memory cells 125), the memory device 100 may include one or more tracking columns 130 disposed next to or integrated into the memory array 120. For example, in FIG. 1, the tracking column 130 may be disposed along one of the edges of the memory array 120 that extend in parallel with the bit lines, BL₀ to BL_{K}. The tracking column 130 can each include a number of tracking memory cells 135 and optionally include a number of dummy memory cells 140. The tracking cells 135 and the dummy memory cells 140 may be configured in any respective numbers, while remaining within the scope of the present disclosure. In some embodiments, a total number of the tracking cells 135 and dummy memory cells 140 may be equal to the number of rows (J). For example, the number of tracking cells 135 may be selected to simulate a worst-case condition in a write and/or read operation.

In some embodiments, the tracking column 130 can further include a tracking word line TKWL 145 and a tracking bit line TKBL 150. In general, each of the tracking memory cells 135 may be operatively coupled to the TKWL 145 and the TKBL 150. However, each of the dummy memory cells 140 may not be operatively coupled to the TKWL 145, but operatively coupled to the TKBL 150. The TKWL 145 and the TKBL 150 are configured to conduct respective tracking signals (e.g., a TKBL signal, a TKWL signal, etc.), which will be discussed in further detail below. By conducting the tracking signals, the TKWL 145 and the TKBL 150 can respectively emulate signal routing delays in a functional memory array (e.g., 120) for a read or write operation at the far edge.

For example, the tracking word line TKWL 145 may include a (e.g., horizontal) portion extending along the rows of the memory array 120 (not expressly shown), and the (e.g., vertical) portion shown in FIG. 1 that extends along the columns of the memory array 120. A length of the vertical portion of the tracking word line TKWL 145 may be approximately equal to a height of the memory array (e.g., a distance from the memory controller 105 to the farthest tracking cell 135 or dummy memory cell 140, according to the orientation of the memory array in FIG. 1); and a length of the horizontal portion of the tracking word line 145 may be approximately equal to a width of the memory array 120 (e.g., a distance along any of the rows from one edge of the array to the other, according to the orientation of the memory array in FIG. 1). Accordingly, a sum of the lengths of the first and second portions of the tracking word line TKWL 145 may be such that the metal routing delay for accessing a cell at the top right corner of the memory array 120 is emulated, e.g., the delay from signal entry at the bottom left, propagating horizontally and vertically, over a path distance equal to the length of a path from one corner to the diagonally opposite corner.

In general, the tracking memory cells 135 do not function as the (nominal) memory cells 125 do in terms of storing data and supporting read/write operations. Rather, the tracking memory cells 135 may originally be a subset of the nominal memory cells 125 but be enlisted, or re-purposed, for timing tracking. For example, the tracking memory cells 135 are bit cells with fixed logic values configured and coupled to one another so as to respond in a predictable way when addressed by test or tracking signals. The dummy memory cells 140 enable the capacitive and resistive environment to be matched closely for accurate modeling of the environment for nominal memory cells. Bit lines that are tracked typically have two factors that determine propagation delay of signals that are carried, namely serial resistance and parallel capacitance. The dummy memory cells 140 have real capacitive load, and mimic the capacitance of bit lines BLs coupled to the nominal memory cells 125.

The memory controller 105 is a hardware component configured to control various operations of the memory array 120 such as, reading data bits from the nominal memory cells 125, writing data bits into the nominal memory cells 125, performing a timing tracking scheme on respective timings of the read/write operation, adjusting (e.g., skipping) the timing tracking scheme based on an operation mode of the memory device 100, etc. In various embodiments, the memory controller 105 can include a number of circuits, each of which may be embodied as logic circuits, analog circuits, or a combination of them, to perform such operations.

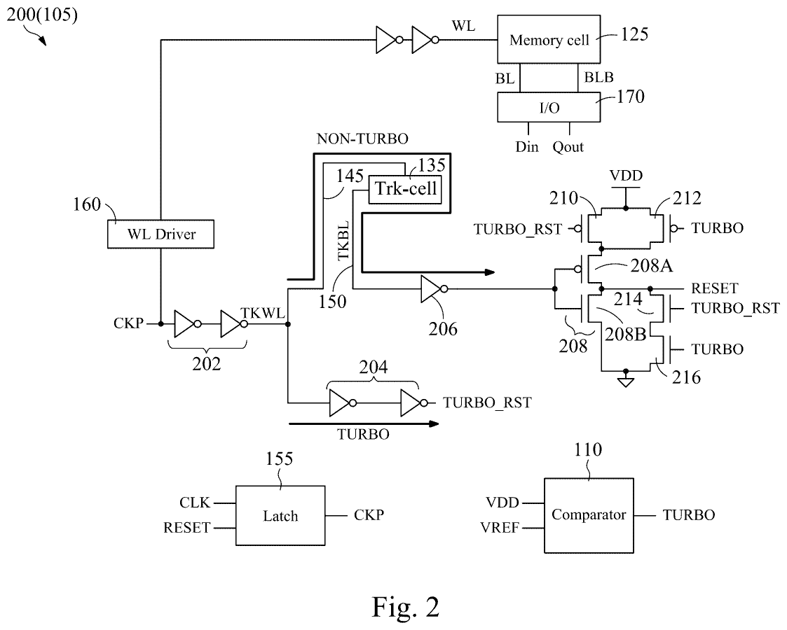

As a representative example, the memory controller 105 can be coupled to a latch 155, and include a TKWL generator and a combination of logic gates. The latch 155 can be integrated into the memory controller 105, in some embodiments. The latch 155 can receive a clock (CLK) signal and a reset (RESET) signal, and provide, based on the CLK signal and the RESET signal, a clock pulse (CKP) signal with a pulse width. The CKP signal can drive a TKWL signal. The pulse width of the CKP signal (or the TKWL signal) has a rising edge, which can be determined by a rising edge of the CLK signal, and a falling edge, which can be determined by a falling edge of the RESET signal. Further, a timing of the falling edge of the RESET signal can be determined according to the operation mode of the memory device 100, which can be selected based on the mode selection signal provided by the comparator 110 and/or one or more other mode selection signals. Various implementations of the memory controller 105 will be discussed in further detail with respect to FIGS. 2, 4, and 5, respectively.

In some embodiments, the memory device 100 can further include various other circuit components such as, for example, a write (or WL) driver/controller 160, an input/output (I/O) circuit 170, etc., each of which may be embodied as logic circuits, analog circuits, or a combination of them. The write driver 160 can provide a voltage or current conducted through one or more word lines WL of the memory array 120. Such a voltage/current may sometimes be referred to as a WL signal. The I/O circuit 170 can sense a voltage or current conducted through one or more bit lines BLs of the memory array 120. For example, the I/O circuit 170 may include a number of sense amplifiers, each of which is operatively coupled to one or more of the bit lines BLs inside the memory array 120.

FIG. 2 illustrates a block diagram of one implementation 200 of the memory controller 105 (FIG. 1), in accordance with various embodiments. Hereinafter, the implementation 200 is referred to as “controller 200.” As a reference, other components of the memory device 100 (e.g., the comparator 110, the nominal memory cell 125, the tracking memory cell 135, the latch 155, the WL driver 160, the I/O circuit 170, etc.) are also shown in FIG. 2. The latch 155 can be integrated into the memory controller 200. It should be understood that the block diagram of FIG. 2 has been simplified, and does not intend to limit the scope of the present disclosure.

As shown, the controller 200 includes a (e.g., even) number of inverters 202, a (e.g., even) number of inverters 204, and a combination of logic gates which include inverters 206-208, p-type transistors 210-212, and n-type transistors 214-216. In some embodiments, the comparator 110 is configured to receive a reference voltage (VREF) and a varying supply voltage (VDD), and to compare the respective voltage levels of VREF and VDD so as to generate a mode selection signal (e.g., TURBO). The TURBO signal may be configured to indicate whether the memory device 100 operates in a non-turbo mode or a turbo mode. For example, when the voltage level of VDD is higher than the voltage level of VREF, the TURBO signal is provided (by the comparator 110) at logic 1, which corresponds to the turbo mode; and when the voltage level of VDD is equal to or lower than the voltage level of VREF, the TURBO signal is provided (by the comparator 110) at logic 0, which corresponds to the non-turbo mode.

The latch 155 is configured to receive a clock signal (CLK) and a reset signal (RESET), and provide a clock pulse signal (CKP). In some embodiments, the latch 155 may be implemented as a Set-Reset (SR) latch, although the latch 155 can be implemented as any other type of latch while remaining within the scope of the present disclosure. In the example of the latch 155 implement as an SR latch with NAND gates, the CLK signal and the RESET signal may be fed into a set input and a reset input of the latch 155. Accordingly, the CKP signal (an output of the latch 155) can be reset (e.g., transitions from logic 1 to logic 0), when the RESET signal (a first input of the latch 155) transitions from logic 1 to logic 0 with the CLK signal (a second input of the latch 155) remains at logic 1. In some embodiments, the CKP signal can drive various circuit components of the memory device 100. For example, the CKP signal can be provided to the WL driver 160, asserting one or more of the word lines WLs of the memory array 120. In another example, the CKP signal can be provided as the TKWL signal through the inverters 202.

Referring still to FIG. 2, the TKWL signal can be provided on the TKWL 145, which can activate the tracking memory cell 135 when in the non-turbo mode, or be utilized to generate an intermediate reset signal (TURBO_RST) when in the turbo mode, in accordance with some embodiments. The TURBO_RST signal may follow the TKWL signal through the even number of inverters 204. Thus, when the TKWL signal is pulled up according to a rising edge of the CKP signal, the TURBO_RST signal is pulled up with a gate delay incurred by the inverters 204; and when the TKWL signal is pulled down according to a falling edge of the CKP signal, the TURBO_RST signal is pulled down with the gate delay incurred by the inverters 204.

Prior to the CKP signal being pulled up (sometimes referred to as a stand-by mode), the TKBL signal present on the TKBL 150 can be pre-charged to logic 1 (e.g., equal to the voltage level VDD). Upon the TKWL signal being pulled up according to a rising edge of the CKP signal (e.g., transitioning to an operation mode which may include at least the non-turbo mode and the turbo mode), the tracking memory cell 135 can be activated by the TKWL signal, which causes the TKBL signal to be pulled down. Through the inverters 206-208, the RESET signal can be pulled down to reset the CKP signal (by the latch 155).

In some embodiments, the inverter 208 can include a p-type transistor 208A and an n-type transistor 208B, with their gate terminals connected to an output of the inverter 206 and their commonly connected source/drain terminals configured to provide the RESET signal. The other source/drain terminal of the transistor 208A can be coupled to the supply voltage VDD through the transistors 210-212; and the commonly connected source/drain terminals of the transistors 208A-B can be coupled to a ground voltage (VSS) through the transistors 212-216. The transistors 210 and 214 can be gated by (or having their gate terminals connected to) the TURBO_RST signal; and the transistors 212 and 216 can be gated by (or having their gate terminals connected to) the TURBO signal.

During the non-turbo mode, the TURBO signal is provided at logic 0 and the TURBO_RST signal (following the TKWL signal) is provided at logic 1. Accordingly, the transistor 210 is turned off, the transistor 212 is turned on, the transistor 214 is turned on, and the transistor 216 is turned off. Essentially, the combination of logic gates (210 to 216) can serve as coupling the VDD and VSS to the last stage of the inverter 208. As a result, during the non-turbo mode, the RESET signal can follow the TKBL signal through the inverters 206-208. Stated another way, during the non-turbo mode, the RESET signal may transition to a different logic state to reset the CKP signal (and then the TKWL signal) based on a first discharging path formed by the TKBL 150. In some embodiments, during the non-turbo mode, the RESET signal can reset the CKP signal, in turn, the TKWL signal, by going through the tracking memory cell 135.

During the turbo mode, the TURBO signal is provided at logic 1 and the TURBO RST signal (following the TKWL signal) is provided at logic 1. Accordingly, the transistor 210 is turned off, the transistor 212 is turned off, the transistor 214 is turned on, and the transistor 216 is turned on. As a result, the RESET signal can be pulled down to logic 0 directly through the turned-on transistors 214-216. During the turbo mode, the RESET signal does not need to wait to transition until the TKBL signal is pulled down. Stated another way, during the turbo mode, the RESET signal may transition to a different logic state to reset the CKP signal (and then the TKWL signal) based on a second discharging path formed by the transistors 214-216. In some embodiments, during the turbo mode, the RESET signal can reset the CKP signal, in turn, the TKWL signal, without going through the tracking memory cell 135.

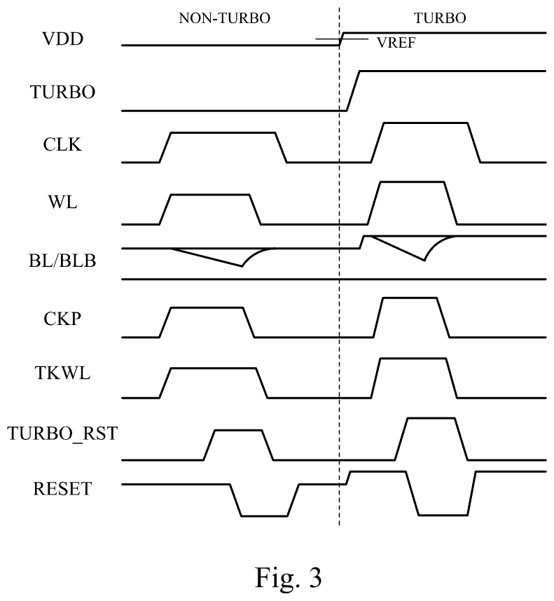

FIG. 3 illustrates waveforms of the forgoing signals varying over time, in accordance with some embodiments. For example, the VDD, the TURBO signal, the CLK signal, a signal present on the WL (WL signal), signals present on the BL and BLB (BL and BLB signals), the CKP signal, the TKWL signal, the TURBO_RST signal, and the RESET signal varying over time during the non-turbo mode and the turbo mode, respectively, are shown.

During the non-turbo mode (e.g., when the voltage level of VDD is lower than the voltage level of VREF), the TURBO signal is provided at logic 0. As the CLK signal is pulled up with the RESET signal remaining at logic 1, the CKP signal is pulled up, causing the WL signal and the TKWL signal to be pulled up. The nominal memory cell 125 and the tracking memory cell 135 can be activated by the WL signal and the TKWL signal, respectively. The BL and BLB signals, induced by the nominal memory cell 125, and the TKBL signal (not shown), induced by the tracking memory cell 135, can respond. Generally, the TKBL signal may transition from logic 1 to logic 0, in response to the tracking memory cell 135 being activated. As shown, the TURBO_SRT signal can follow the TKWL signal. In some embodiments, during the non-turbo mode, the RESET signal may not transition to logic 0 until the TKBL signal transitions to logic 0.

During the turbo mode (e.g., when the voltage level of VDD is higher than the voltage level of VREF), the TURBO signal is provided at logic 1. As the CLK signal is pulled up with the RESET signal remaining at logic 1, the CKP signal is pulled up, causing the WL signal and the TKWL signal to be pulled up. The nominal memory cell 125 and the tracking memory cell 135 can be activated by the WL signal and the TKWL signal, respectively. The BL and BLB signals, induced by the nominal memory cell 125, and the TKBL signal (not shown), induced by the tracking memory cell 135, can respond. Still, the TURBO_SRT signal can follow the TKWL signal. However, in some embodiments, during the turbo mode, the RESET signal can directly transition to logic 0, without waiting for the TKBL signal to transition.

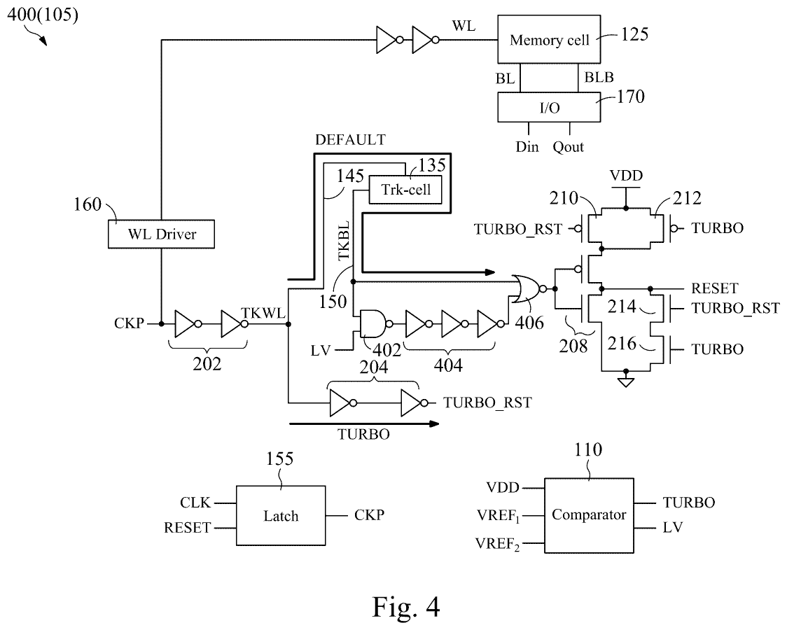

FIG. 4 illustrates a block diagram of one implementation 400 of the memory controller 105 (FIG. 1), in accordance with various embodiments. Hereinafter, the implementation 400 is referred to as “controller 400.” As a reference, other components of the memory device 100 (e.g., the comparator 110, the nominal memory cell 125, the tracking memory cell 135, the latch 155, the WL driver 160, the I/O circuit 170, etc.) are also shown in FIG. 4. The latch 155 can be integrated into the memory controller 400. It should be understood that the block diagram of FIG. 4 has been simplified, and does not intend to limit the scope of the present disclosure.

Similar to the controller 200 including the inverters 202-204 and 208, the p-type transistors 210-212, and the n-type transistors 214-216. In some embodiments, the controller 400 may replace the inverter 206 with a NAND gate 402, an odd number of inverters 404, and a NOR gate 406. Accordingly, the comparator 110 is configured to receive a first reference voltage (VREF₁), a second reference voltage (VREF₂), and a varying supply voltage (VDD), and to compare the respective voltage levels of VREF₁, VREF₂, and VDD so as to generate a plural of mode selection signals (e.g., LV and TURBO). In some embodiments, the voltage level of VREF₁ is lower than the voltage level of VREF₂.

The LV signal may be configured to indicate whether the memory device 100 operates in a low-voltage mode; and the TURBO signal may be configured to indicate whether the memory device 100 operates in a turbo mode. Other than the turbo mode and the low-voltage mode, the memory device 100 can operate in a default mode (similar to the non-turbo mode described with respect to FIGS. 2-3).

For example, when the voltage level of VDD is higher than the voltage level of VREF₂, the TURBO signal and the LV signal are provided (by the comparator 110) at logic 1 and at logic 0, respectively, which corresponds to the turbo mode; when the voltage level of VDD is higher than VREF₁ but equal to or lower than the voltage level of VREF₂, the TURBO signal and the LV signal are provided (by the comparator 110) at logic 0 and at logic 0, respectively, which corresponds to the default mode; and when the voltage level of VDD is equal to or lower than the voltage level of VREF₁, the TURBO signal and the LV signal are provided (by the comparator 110) at logic 0 and at logic 1, respectively, which corresponds to the low-voltage mode.

The latch 155 is configured to receive a clock signal (CLK) and a reset signal (RESET), and provide a clock pulse signal (CKP). In some embodiments, the latch 155 may be implemented as a Set-Reset (SR) latch, although the latch 155 can be implemented as any other type of latch while remaining within the scope of the present disclosure. In the example of the latch 155 implement as an SR latch with NAND gates, the CLK signal and the RESET signal may be fed into a set input and a reset input of the latch 155. Accordingly, the CKP signal (an output of the latch 155) can be reset (e.g., transitions from logic 1 to logic 0), when the RESET signal (a first input of the latch 155) transitions from logic 1 to logic 0 with the CLK signal (a second input of the latch 155) remains at logic 1. In some embodiments, the CKP signal can drive various circuit components of the memory device 100. For example, the CKP signal can be provided to the WL driver 160, asserting one or more of the word lines WLs of the memory array 120. In another example, the CKP signal can be provided as the TKWL signal through the inverters 202.

Referring still to FIG. 4, the TKWL signal can be provided on the TKWL 145, which can activate the tracking memory cell 135 when in the default or low-voltage mode, or be utilized to generate an intermediate reset signal (TURBO_RST) when in the turbo mode, in accordance with some embodiments. The TURBO_RST signal may follow the TKWL signal through the even number of inverters 204. Thus, when the TKWL signal is pulled up according to a rising edge of the CKP signal, the TURBO_RST signal is pulled up with a gate delay incurred by the inverters 204; and when the TKWL signal is pulled down according to a falling edge of the CKP signal, the TURBO_RST signal is pulled down with the gate delay incurred by the inverters 204.

Prior to the CKP signal being pulled up (sometimes referred to as a stand-by mode), the TKBL signal present on the TKBL 150 can be pre-charged to logic 1 (e.g., equal to the voltage level VDD). Upon the TKWL signal being pulled up according to a rising edge of the CKP signal (e.g., transitioning to an operation mode which may include at least the low-voltage mode, the default mode, and the turbo mode), the tracking memory cell 135 can be activated by the TKWL signal, which causes the TKBL signal to be pulled down. Through the NAND gate 402, the inverters 404, the NOR gate 406, and the inverter 208, the RESET signal can be pulled down to reset the CKP signal (by the latch 155).

During the low-voltage mode, the LV signal is provided at logic 1, the TURBO signal is provided at logic 0, and the TURBO_RST signal (following the TKWL signal) is provided at logic 1. Accordingly, the NAND gate 402 can output a signal with logic 1 by NAND'ing the LV signal (provided at logic 1) and the TKBL signal (discharged to logic 0). Through the odd number of inverters 404, the NOR gate 406 can receive its inputs of a pair of logic 0 so as to output a signal with logic 1. Further, the transistor 210 is turned off, the transistor 212 is turned on, the transistor 214 is turned on, and the transistor 216 is turned off. Essentially, the combination of logic gates (210 to 216) can serve as coupling the VDD and VSS to the last stage of the inverter 208. As a result, during the low-voltage mode, the RESET signal can follow the output signal of the NOR gate 406 through the inverter 208, e.g., logic 0. In some embodiments, during the low-voltage mode, the RESET signal can reset the CKP signal, in turn, the TKWL signal, by going through the tracking memory cell 135 and the logic gates 402 to 406.

During the default mode, the LV signal is provided at logic 0, the TURBO signal is provided at logic 0, and the TURBO_RST signal (following the TKWL signal) is provided at logic 1. Accordingly, the transistor 210 is turned off, the transistor 212 is turned on, the transistor 214 is turned on, and the transistor 216 is turned off. Essentially, the combination of logic gates (210 to 216) can serve as coupling the VDD and VSS to the last stage of the inverter 208. As a result, during the default mode, the RESET signal can follow the TKBL signal through the inverters 206-208. In some embodiments, during the default mode, the RESET signal can reset the CKP signal, in turn, the TKWL signal, by going through the tracking memory cell 135.

During the turbo mode, the TURBO signal is provided at logic 1 and the TURBO_RST signal (following the TKWL signal) is provided at logic 1. Accordingly, the transistor 210 is turned off, the transistor 212 is turned off, the transistor 214 is turned on, and the transistor 216 is turned on. As a result, the RESET signal can be pulled down to logic 0 directly through the turned-on transistors 214-216. Stated another way, during the turbo mode, the RESET signal does not need to wait to transition until the TKBL signal is pulled down. In some embodiments, during the turbo mode, the RESET signal can reset the CKP signal, in turn, the TKWL signal, without going through the tracking memory cell 135.

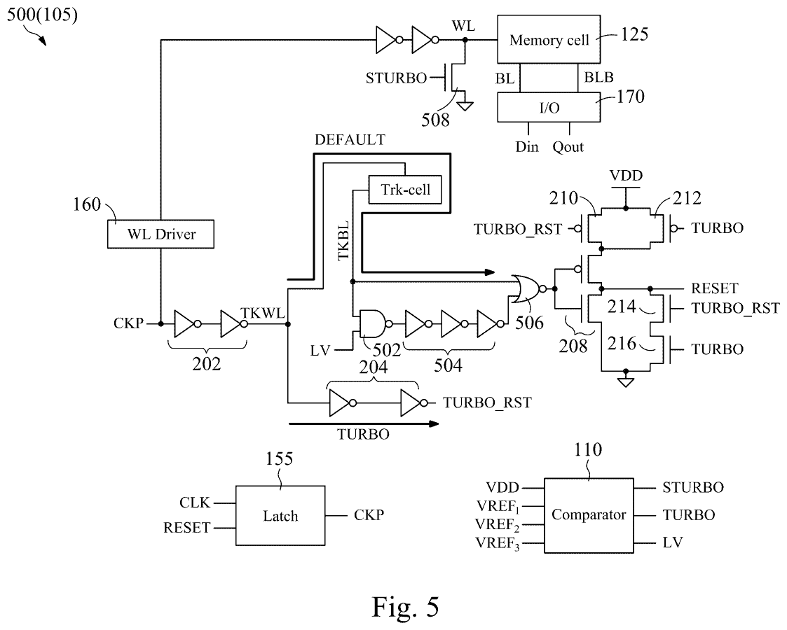

FIG. 5 illustrates a block diagram of one implementation 500 of the memory controller 105 (FIG. 1), in accordance with various embodiments. Hereinafter, the implementation 500 is referred to as “controller 500.” As a reference, other components of the memory device 100 (e.g., the comparator 110, the nominal memory cell 125, the tracking memory cell 135, the latch 155, the WL driver 160, the I/O circuit 170, etc.) are also shown in FIG. 5. The latch 155 can be integrated into the memory controller 500. It should be understood that the block diagram of FIG. 5 has been simplified, and does not intend to limit the scope of the present disclosure.

Similar to the controller 200 including the inverters 202-204 and 208, the p-type transistors 210-212, and the n-type transistors 214-216. In some embodiments, the controller 500 may replace the inverter 206 with a NAND gate 502, an odd number of inverters 504, and a NOR gate 506, and may further include an n-type transistor 508 coupled to the word line WL of the memory array 120. Accordingly, the comparator 110 is configured to receive a first reference voltage (VREF₁), a second reference voltage (VREF₂), a third reference voltage (VREF₃), and a varying supply voltage (VDD), and to compare the respective voltage levels of VREF₁, VREF₂, VREF₃, and VDD so as to generate a plural of mode selection signals (e.g., LV, TURBO, and STURBO). In some embodiments, the voltage level of VREF₁ is lower than the voltage level of VREF₂, and the voltage level of VREF₂ is lower than the voltage level of VREF₃.

The LV signal may be configured to indicate whether the memory device 100 operates in a low-voltage mode; the TURBO signal may be configured to indicate whether the memory device 100 operates in a turbo mode; and the STURBO signal may be configured to indicate whether the memory device 100 operates in a super turbo mode. Other than the super turbo mode, the turbo mode and the low-voltage mode, the memory device 100 can operate in a default mode (similar to the non-turbo mode described with respect to FIGS. 2-3).

For example, when the voltage level of VDD is higher than the voltage level of VREF₃, the STURBO signal, the TURBO signal, and the LV signal are provided (by the comparator 110) at logic 1, at logic 1/0, and at logic 0, respectively, which corresponds to the super turbo mode; when the voltage level of VDD is lower than or equal to VREF₃ but higher than the voltage level of VREF₂, the STURBO signal, the TURBO signal, and the LV signal are provided (by the comparator 110) at logic 0, at logic 1, and at logic 0, respectively, which corresponds to the turbo mode; when the voltage level of VDD is higher than VREF₁ but equal to or lower than the voltage level of VREF₂, the STURBO signal, the TURBO signal, and the LV signal are provided (by the comparator 110) at logic 0, at logic 0, and at logic 0, respectively, which corresponds to the default mode; and when the voltage level of VDD is equal to or lower than the voltage level of VREF₁, the STURBO signal, the TURBO signal, and the LV signal are provided (by the comparator 110) at logic 0, at logic 0, and at logic 1, respectively, which corresponds to the low-voltage mode.

The latch 155 is configured to receive a clock signal (CLK) and a reset signal (RESET), and provide a clock pulse signal (CKP). In some embodiments, the latch 155 may be implemented as a Set-Reset (SR) latch, although the latch 155 can be implemented as any other type of latch while remaining within the scope of the present disclosure. In the example of the latch 155 implement as an SR latch with NAND gates, the CLK signal and the RESET signal may be fed into a set input and a reset input of the latch 155. Accordingly, the CKP signal (an output of the latch 155) can be reset (e.g., transitions from logic 1 to logic 0), when the RESET signal (a first input of the latch 155) transitions from logic 1 to logic 0 with the CLK signal (a second input of the latch 155) remains at logic 1. In some embodiments, the CKP signal can drive various circuit components of the memory device 100. For example, the CKP signal can be provided to the WL driver 160, asserting one or more of the word lines WLs of the memory array 120. In another example, the CKP signal can be provided as the TKWL signal through the inverters 202.

Referring still to FIG. 5, the TKWL signal can be provided on the TKWL 145, which can activate the tracking memory cell 135 when in the default or low-voltage mode, or be utilized to generate an intermediate reset signal (TURBO_RST) when in the turbo mode, in accordance with some embodiments. The TURBO_RST signal may follow the TKWL signal through the even number of inverters 204. Thus, when the TKWL signal is pulled up according to a rising edge of the CKP signal, the TURBO_RST signal is pulled up with a gate delay incurred by the inverters 204; and when the TKWL signal is pulled down according to a falling edge of the CKP signal, the TURBO_RST signal is pulled down with the gate delay incurred by the inverters 204.

Prior to the CKP signal being pulled up (sometimes referred to as a stand-by mode), the TKBL signal present on the TKBL 150 can be pre-charged to logic 1 (e.g., equal to the voltage level VDD). Upon the TKWL signal being pulled up according to a rising edge of the CKP signal (e.g., transitioning to an operation mode which may include at least the low-voltage mode, the default mode, and the turbo mode), the tracking memory cell 135 can be activated by the TKWL signal, which causes the TKBL signal to be pulled down. Through the NAND gate 502, the inverters 504, the NOR gate 506, and the inverter 208, the RESET signal can be pulled down to reset the CKP signal (by the latch 155).

During the low-voltage mode, the LV signal is provided at logic 1, with the other mode selection signals (the STURBO signal and TURBO signal) each provided at logic 0, and the TURBO_RST signal (following the TKWL signal) is provided at logic 1. Accordingly, the NAND gate 502 can output a signal with logic 1 by NAND'ing the LV signal (provided at logic 1) and the TKBL signal (discharged to logic 0). Through the odd number of inverters 504, the NOR gate 506 can receive its inputs of a pair of logic 0 so as to output a signal with logic 1. Further, the transistor 210 is turned off, the transistor 212 is turned on, the transistor 214 is turned on, and the transistor 216 is turned off. Essentially, the combination of logic gates (210 to 216) can serve as coupling the VDD and VSS to the last stage of the inverter 208. As a result, during the low-voltage mode, the RESET signal can follow the output signal of the NOR gate 506 through the inverter 208, e.g., logic 0. Further, the transistor 508 is turned off (through the STURBO signal), which does not suppress the voltage level present on the word line WL. In some embodiments, during the low-voltage mode, the RESET signal can reset the CKP signal, in turn, the TKWL signal, by going through the tracking memory cell 135 and the logic gates 502 to 506.

During the default mode, all the mode selection signals (the LV signal, the TURBO signal, and the STURBO signal) are provided at logic 0, and the TURBO_RST signal (following the TKWL signal) is provided at logic 1. Accordingly, the transistor 210 is turned off, the transistor 212 is turned on, the transistor 214 is turned on, and the transistor 216 is turned off. Essentially, the combination of logic gates (210 to 216) can serve as coupling the VDD and VSS to the last stage of the inverter 208. As a result, during the default mode, the RESET signal can follow the TKBL signal through the inverters 206-208. Further, the transistor 508 is turned off (through the STURBO signal), which does not suppress the voltage level present on the word line WL. In some embodiments, during the default mode, the RESET signal can reset the CKP signal, in turn, the TKWL signal, by going through the tracking memory cell 135.

During the turbo mode, the TURBO signal is provided at logic 1, with other mode selection signals (the STURBO signal and the LV signal) provided at logic 0, and the TURBO_RST signal (following the TKWL signal) is provided at logic 1. Accordingly, the transistor 210 is turned off, the transistor 212 is turned off, the transistor 214 is turned on, and the transistor 216 is turned on. As a result, the RESET signal can be pulled down to logic 0 directly through the turned-on transistors 214-216. Stated another way, during the turbo mode, the RESET signal does not need to wait to transition until the TKBL signal is pulled down. Further, the transistor 508 is turned off (through the STURBO signal), which does not suppress the voltage level present on the word line WL. In some embodiments, during the turbo mode, the RESET signal can reset the CKP signal, in turn, the TKWL signal, without going through the tracking memory cell 135.

During the super turbo mode, the STURBO signal is provided at logic 1, the TURBO signal is provided at logic 0 or 1, the LV signal is provided at logic 0, and the TURBO_RST signal (following the TKWL signal) is provided at logic 1. Accordingly, the transistor 210 is turned off, the transistor 212 is turned off, the transistor 214 is turned on, and the transistor 216 is turned on. As a result, the RESET signal can be pulled down to logic 0 directly through the turned-on transistors 214-216. Stated another way, during the turbo mode, the RESET signal does not need to wait to transition until the TKBL signal is pulled down. Different from the low-voltage/default/turbo modes, the transistor 508 is turned on (through the STURBO signal), which causes the voltage level present on the word line WL to be suppressed. In some embodiments, during the super turbo mode, the RESET signal can reset the CKP signal, in turn, the TKWL signal, without going through the tracking memory cell 135.

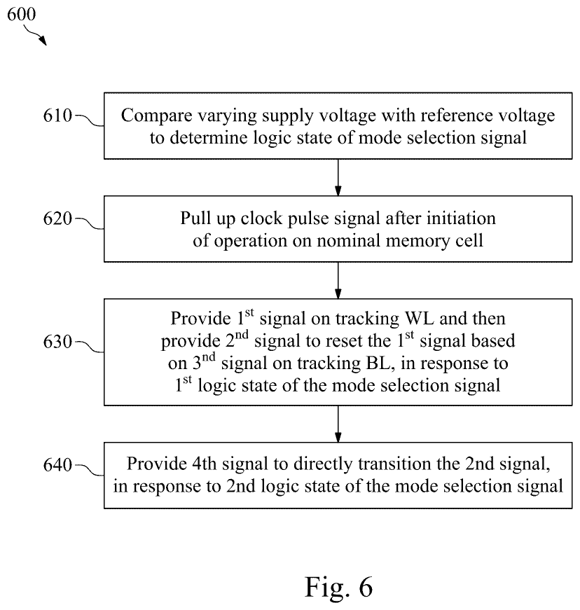

FIG. 6 illustrates a flow chart of a method 600 for operating a memory device including a memory controller configured to skip a tracking scheme to reset a tracking word line signal based on an operation mode of the memory device, in accordance with various embodiments. For example, at least some of the operations of the method 600 can be performed by the controllers discussed with respect to FIGS. 1-5. Thus, in the following discussion of the methods 600, the reference numerals used at least in FIGS. 1-5 may be reused. It is noted that the method 600 is merely an example and is not intended to limit the present disclosure. Accordingly, it is understood that additional operations may be provided before, during, and after the method 600 of FIG. 6, and that some other operations may only be briefly described herein.

The method 600 may start with operation 610 of comparing a voltage level of a varying supply voltage (e.g., VDD) with a reference voltage (e.g., VREF) to determine a logic state of a mode selection signal (e.g., the TURBO signal). In some embodiments, the VDD is configured to power a memory array (e.g., 120) of the disclosed memory device, which includes a plurality of nominal memory cells (e.g., 125) and at least one tracking memory cell (e.g., 135). The memory device can further include a comparator (e.g., 110) that is configured to generate the TURBO signal with a logic state based on comparing the voltage levels between the varying VDD and the fixed VREF. For example, when the voltage level of VDD is higher than the voltage level of VREF, a memory controller (e.g., 200) of the disclosed memory device can receive the TURBO signal with a first logic state (e.g., logic 0); and when the voltage level of VDD is equal to or lower than the voltage level of VREF, the memory controller can receive the TURBO signal with a second logic state (e.g., logic 1).

The method 600 may proceed to operation 620 of pulling up a clock pulse signal (e.g., CKP signal) after an operation performed on the nominal memory cell 125 is initiated. The operation may refer to a write operation and/or a read operation performed on the nominal memory cell 125. In some embodiments, a clock generator can provide a latch (e.g., 155) with a clock signal (e.g., the CLK signal) with a rising edge. The latch 155 can also receive a reset signal (e.g., the RESET signal) configured to reset a tracking word line signal (e.g., the TKWL signal). Upon identifying the rising edge of the received CLK signal and the RESET signal being held at logic 1, the latch 155 can pull up various signals to operate the memory device such as, for example, the TKWL signal, a signal present on the word line WL of the nominal memory cell (a WL signal), etc.

The method 600 may proceed to operation 630 of providing a first signal (e.g., the TKWL signal) on a tracking word line connected to the tracking memory cell and then providing a second signal (e.g., the RESET signal) to reset the first signal based on a third signal (e.g., the TKBL signal) present on a tracking bit line connected to the tracking memory cell, in response to identifying the logic state of the mode selection signal being equal to the first logic state. Continuing with the foregoing example, upon identifying that the TURBO signal is provided at logic 0, the memory controller 200 can activate the tracking memory cell 135 through the pulled-up TKWL signal. Following the activation of the tracking memory cell 135, the memory controller 200 can transition the RESET signal upon detecting that the TKBL signal has fallen to a voltage level corresponding to logic 0. In some embodiments, when the TURBO signal is provided at logic 0, the memory controller 200 may wait to transition the RESET signal until the TKBL signal transitions to logic 0. Further, the memory controller 200 can transition the RESET signal through a combination of logic gates (e.g., 206 to 216), with the transistors 212 and 216 being turned off and with the transistors 210 and 214 being turned on.

The method 600 may proceed to operation 640 of providing a fourth signal (e.g., the TURBO_RST signal) directly based on the first signal, wherein the fourth signal is configured to directly transition the second signal, in response to identifying the logic state of the mode selection signal being equal to the second logic state. Continuing with the foregoing example, upon identifying that the TURBO signal is provided at logic 1, the memory controller 200 may not wait to transition the RESET signal with going through the transition of the TKBL signal. In some embodiments, the memory controller 200 can directly transition the RESET signal through a portion of the combination of logic gates (e.g., 206 to 216). For example, with the TURBO signal being equal to logic 1 (and the TURBO_RST signal held at logic 1), the transistors 214 and 216 are turned on, and the transistors 210 and 212 are turned off. Accordingly, the RESET signal can be pulled down to logic 0 through the transistors 214 and 216.

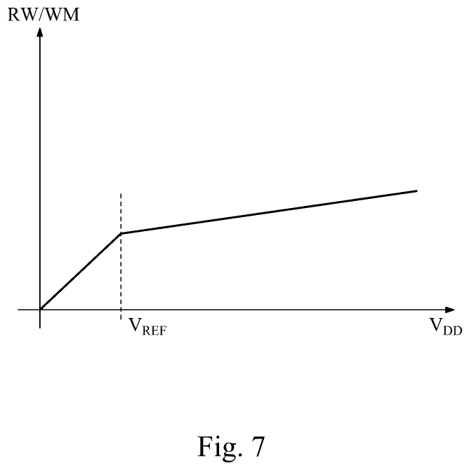

FIG. 7 illustrates an example plot of one or more performance characteristics of the disclosed memory device versus the voltage level of a supply voltage (e.g., VDD) provided to the memory device, in accordance with some embodiments. For example, the performance characteristic may be a read margin (RM) or a write margin (WM) of the memory device. As shown, the RM/WM may increase with a first slope in accordance with the increasing VDD, when the VDD is equal to or lower than a reference voltage (VREF); and increase with a second slope in accordance with the increasing VDD, when the VDD is higher than the VREF. In some embodiments, the first slope can be higher (e.g., steeper) than the second slope, which may advantageously reduce power waste of the memory device when operating with the higher supply voltage.

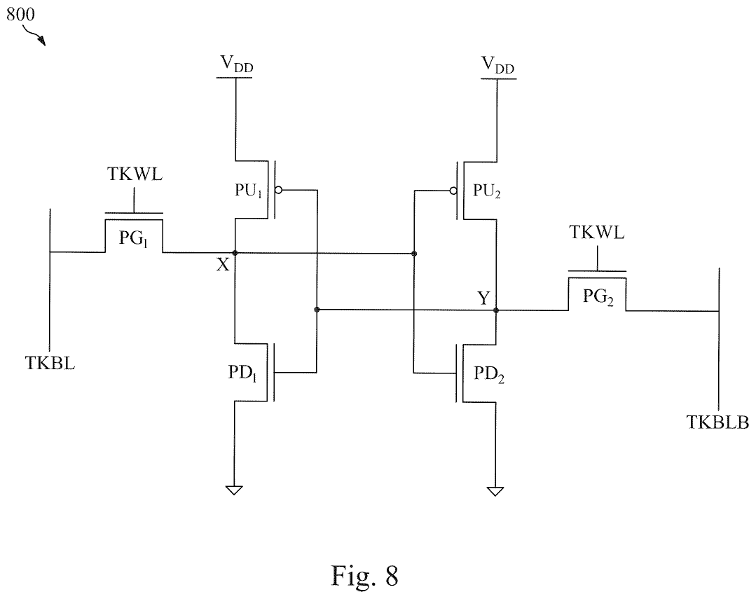

FIGS. 8, 9, and 10 illustrate respective example circuit diagrams of the tracking memory cell 135 (FIG. 1), in accordance with some embodiments. Hereinafter, the circuit diagrams of FIGS. 8 to 10 are referred to as tracking memory cell 800, tracking memory cell 900, and tracking memory cell 1000, respectively. The tracking memory cells 800 to 1000 are each substantially similar to the nominal memory cell 125 which may be implemented in a 6T SRAM configuration. For example, each of the tracking memory cells 800 to 1000 may include a pair of n-type pass-gate transistors, PG1 and PG2, a pair of p-type pull-up transistors, PU1 and PU2, and a pair of n-type pull-down transistors PD1 and PD2. However, it should be understood that the circuit diagram of FIGS. 8-10 are provided for illustrative purposes and does not necessarily intend to limit the scope of the present disclosure.

In FIG. 8, both the PG1 and PG2 transistors have their gate terminals connected to a tracking word line TKWL. A first source/drain terminal of the PG1 transistor is connected to a tracking bit line TKBL and a second source/drain terminal of the PG1 transistor is connected to an output (X node) of a first inverter formed by the PU1 transistor and the PD1 transistor; and a first source/drain terminal of the PG2 transistor is connected to a complementary tracking bit line TKBLB and a second source/drain terminal of the PG2 transistor is connected to an output (Y node) of a second inverter formed by the PU2 transistor and the PD2 transistor. An input of the first inverter is connected to the Y node; and an input of the second inverter is connected to the X node.

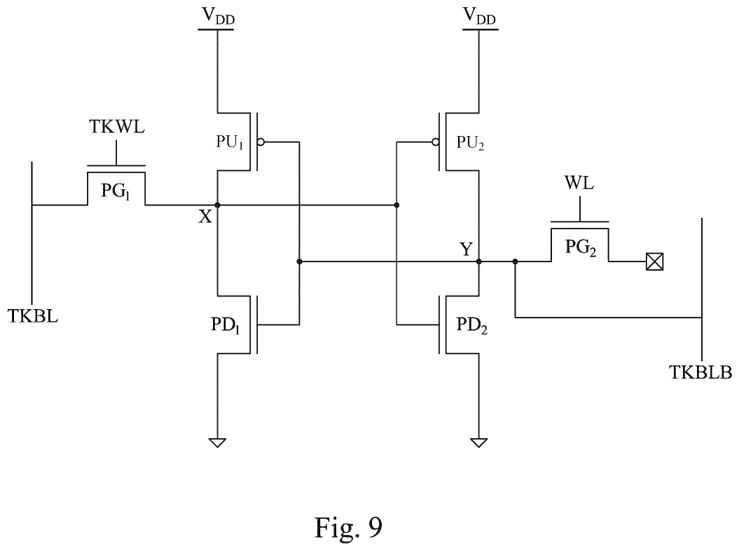

In FIG. 9, the PG1 transistor may have its gate terminal connected to a tracking word line TKWL, while the PG2 transistor may have it gate terminal connected to a nominal word line WL. Further, a first source/drain terminal of the PG1 transistor is connected to a tracking bit line TKBL and a second source/drain terminal of the PG1 transistor is connected to an output (X node) of a first inverter formed by the PU1 transistor and the PD1 transistor; and a first source/drain terminal of the PG2 transistor is electrically floating, and a second source/drain terminal of the PG2 transistor is connected to an output (Y node) of a second inverter formed by the PU2 transistor and the PD2 transistor and is further connected to a complementary tracking bit line TKBLB. An input of the first inverter is connected to the Y node; and an input of the second inverter is connected to the X node.

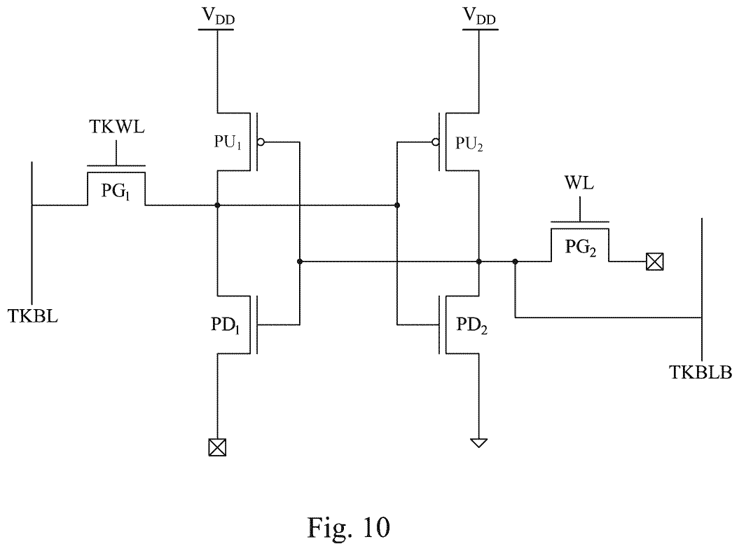

In FIG. 10, the PG1 transistor may have its gate terminal connected to a tracking word line TKWL, while the PG2 transistor may have it gate terminal connected to a nominal word line WL. Further, a first source/drain terminal of the PG1 transistor is connected to a tracking bit line TKBL and a second source/drain terminal of the PG1 transistor is connected to an output (X node) of a first inverter formed by the PUI transistor and the PD1 transistor; and a first source/drain terminal of the PG2 transistor is electrically floating, and a second source/drain terminal of the PG2 transistor is connected to an output (Y node) of a second inverter formed by the PU2 transistor and the PD2 transistor and is further connected to a complementary tracking bit line TKBLB. An input of the first inverter is connected to the Y node; and an input of the second inverter is connected to the X node. Different from FIG. 9, one of the source/drain terminals of the PD1 transistor, not connected to the PUI transistor, may be electrically floating.

In one aspect of the present disclosure, a circuit is disclosed. The circuit includes a memory array comprising a plurality of nominal memory cells and at least a tracking memory cell, the tracking memory cell being coupled to a tracking bit line and a tracking word line; a comparator configured to compare a reference voltage with a varying supply voltage so as to determine a logic state of a mode selection signal; and a controller. The controller is configured to in response to receiving the logic state of the mode selection signal being equal to a first logic state, provide a first signal on the tracking word line and provide a second signal to reset the first signal based on a third signal present along a first discharging path on the tracking bit line; and in response to receiving the logic state of the mode selection signal being equal to a second logic state, provide the first signal on the tracking word line and provide the second signal to reset the first signal based on a fourth signal configured to form a second discharging path different from the first discharging path.

In another aspect of the present disclosure, a circuit is disclosed. The circuit includes a controller configured to generate a tracking word line signal present on a tracking word line coupled to one or more tracking memory cells, based on a clock pulse signal; and a comparator configured to determine a mode selection signal being equal to (i) a first logic state in response to identifying that a varying supply voltage is equal to or lower than a reference voltage; or (ii) a second logic state in response to identifying that the varying supply voltage is higher than the reference voltage. The controller is further configured to reset the tracking word line signal through the one or more tracking memory cells and a combination of logic gates of the controller, when the mode selection signal is determined at the first logic state; and reset the tracking word line signal through a portion of the combination of logic gates, when the mode selection signal is determined at the second logic state.

In yet another aspect of the present disclosure, a method for operating memory circuits is disclosed. The method includes comparing a voltage level of a varying supply voltage with a reference voltage to determine a logic state of a mode selection signal, wherein the supply voltage is configured to power a memory array comprising a plurality of nominal memory cells and a tracking memory cell. The method includes in response to identifying the logic state being equal to a first logic state, providing a first signal on a tracking word line connected to the tracking memory cell and then providing a second signal to reset the first signal based on a third signal present on a tracking bit line connected to the tracking memory cell. The method includes in response to identifying the logic state being equal to a second logic state, providing a fourth signal directly based on the first signal, wherein the fourth signal is configured to directly transition the second signal.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a memory array comprising a plurality of nominal memory cells and at least a tracking memory cell, the tracking memory cell being coupled to a tracking bit line and a tracking word line;
a comparator configured to compare a reference voltage with a varying supply voltage so as to determine a logic state of a mode selection signal; and
a controller configured to:
in response to receiving the logic state of the mode selection signal being equal to a first logic state, provide a first signal on the tracking word line and provide a second signal to reset the first signal based on a third signal present along a first discharging path on the tracking bit line; and
in response to receiving the logic state of the mode selection signal being equal to a second logic state, provide the first signal on the tracking word line and provide the second signal to reset the first signal based on a fourth signal configured to form a second discharging path different from the first discharging path.

2. The circuit of claim 1, wherein the logic state of the mode selection signal is equal to the first logic state, when the varying supply voltage has a voltage level equal to or lower than the reference voltage.

3. The circuit of claim 1, wherein the logic state of the mode selection signal is equal to the second logic state, when the varying supply voltage has a voltage level higher than the reference voltage.

4. The circuit of claim 1, wherein the controller comprises:
a number of first inverters coupled to the tracking word line through the tracking bit line and the tracking memory cell; and
a number of second inverters directly coupled to the tracking word line.

5. The circuit of claim 4, wherein a last stage of the first inverters is configured to generate the second signal, and a last stage of the second inverters is configured to generate the fourth signal.

6. The circuit of claim 5, wherein the controller comprises:
a first p-type transistor coupled between the varying supply voltage and the last stage of the first inverters, and gated by the fourth signal; and
a second p-type transistor coupled between the varying supply voltage and the last stage of the first inverters, and gated by the mode selection signal.

7. The circuit of claim 6, wherein the controller comprises:
a first n-type transistor and a second n-type transistor coupled in series, which are collectively coupled between an output of the last stage of the first inverters and a ground voltage.

8. The circuit of claim 7, wherein the first n-type transistor is gated by the mode selection signal, and the second n-type transistor is gated by the fourth signal, and wherein the first n-type transistor and the second n-type transistor, upon being activated, are configured to form the second discharging path.

9. The circuit of claim 1, wherein the controller comprises a latch configured to:
receive a clock signal and the second signal; and
provide a clock pulse signal based on the clock signal and the second signal, wherein the clock pulse signal is configured to drive the first signal.

10. A circuit, comprising:
a controller configured to generate a tracking word line signal present on a tracking word line coupled to one or more tracking memory cells, based on a clock pulse signal; and
a comparator configured to determine a mode selection signal being equal to (i) a first logic state in response to identifying that a varying supply voltage is equal to or lower than a reference voltage; or (ii) a second logic state in response to identifying that the varying supply voltage is higher than the reference voltage;
wherein the controller is further configured to:
reset the tracking word line signal through the one or more tracking memory cells and a combination of logic gates of the controller, when the mode selection signal is determined at the first logic state; and
reset the tracking word line signal through a portion of the combination of logic gates, when the mode selection signal is determined at the second logic state.

11. The circuit of claim 10, wherein the combination of logic gates comprise:
a number of first inverters coupled to the one or more tracking memory cells through a tracking bit line;
a number of second inverters directly coupled to the tracking word line;
a first p-type transistor coupled between the varying supply voltage and a last stage of the first inverters;
a second p-type transistor coupled between the varying supply voltage and the last stage of the first inverters; and
a first n-type transistor and a second n-type transistor coupled in series, which are collectively coupled between an output of the last stage of the first inverters and a ground voltage.

12. The circuit of claim 11, wherein the last stage of the first inverters is configured to generate a first reset signal at the output to reset the tracking word line signal, and a last stage of the second inverters is configured to generate a second reset signal.

13. The circuit of claim 12, wherein the first p-type transistor is gated by the mode selection signal.

14. The circuit of claim 12, wherein the second p-type transistor is gated by the second reset signal.

15. The circuit of claim 12, wherein the first p-type transistor is gated by the mode selection signal.

16. The circuit of claim 12, wherein the second p-type transistor is gated by the second reset signal.

17. The circuit of claim 12, wherein the controller comprises a latch configured to:
receive a clock signal and the first reset signal; and
provide the clock pulse signal based on the clock signal and the first reset signal, wherein the clock pulse signal is configured to drive the tracking word line signal.

18. The circuit of claim 10, wherein the first logic state and the second logic state of the mode selection signal correspond to a normal-performance mode of the circuit and a high-performance mode of the circuit, respectively.

19. A method, comprising:
comparing a voltage level of a varying supply voltage with a reference voltage to determine a logic state of a mode selection signal, wherein the varying supply voltage is configured to power a memory array comprising a plurality of nominal memory cells and a tracking memory cell;
in response to identifying the logic state being equal to a first logic state, providing a first signal on a tracking word line connected to the tracking memory cell and then providing a second signal to reset the first signal based on a third signal present on a tracking bit line connected to the tracking memory cell; and
in response to identifying the logic state being equal to a second logic state, providing a fourth signal directly based on the first signal, wherein the fourth signal is configured to directly transition the second signal.

20. The method of claim 19, further comprising:
determining the logic state equal to the first logic state, upon identifying that the voltage level is equal to or lower than the reference voltage; and
determining the logic state equal to the second logic state, upon identifying that the voltage level is higher than the reference voltage.
